(19) United States
(12) Patent Application Publication
(10) Pub. No.: US 2026/0122853 A1
(43) Pub. Date: Apr. 30, 2026

(54) HIGH-HEAT-DISSIPATION HYBRID-COMPOSITE HEAT SINK

(71) Applicants: Janie LEE, Seongnam-si (KR); Minho NAM, Ansan-si (KR)

(72) Inventors: Janie LEE, Seongnam-si (KR); Minho NAM, Ansan-si (KR)

(21) Appl. No.: 18/947,914

(22) Filed: Nov. 14, 2024

(30) Foreign Application Priority Data
Oct. 28, 2024 (KR) 10-2024-0148512

(51) Int. Cl. H05K 7/20

(52) U.S. Cl. CPC H05K 7/2039

(57) ABSTRACT

Disclosed is a high-heat-dissipation hybrid-composite heat sink and has a configuration in which an attachment such as a heat spreader or a shield can is bonded without an air gap through surface-to-surface bonding to a heat sink made of a plate having high thermal conductivity. An ultra-compact and ultra-light heat dissipation structure improves heat dissipation performance and has light weight and small volume by solving problems of a die casting material in the prior art which has heat dissipation performance degraded due to inclusion of a foreign substance and has large volume and heavy weight.

### BACKGROUND OF THE PRESENT INVENTION

### Field of the Present Invention

The present invention relates to a heat sink for dissipating heat from various types of electronic devices.

### Description of the Related Art

Recently, the era of ubiquitous and digital convergence related to displays and AI autonomous driving, which are rapidly developing, is entering. Accordingly, various components thereof are rapidly becoming smaller and slimmer.

In this way, as various components are integrated, more heat is generated, and this heat emission not only reduces the functions of the components, but also causes malfunction of surrounding components and deterioration of the substrate.

In particular, high-power consumption products such as power devices and LED modules generate a lot of heat, and it is difficult to control the heat emission.

Accordingly, there is an increasing demand for lightweight heat sinks, but there is an urgent need for research to overcome the heat dissipation limitations, large volume, and heavy weight of aluminum die-casting materials, which are most commonly used in automobiles, electric vehicles, and LEDs.

More specifically, the aluminum die-casting materials are composed of two types of alloys such as ADC10 and ADC12, which have good structural and mechanical properties, accounting for about 98% of die-casting production. These materials are mainly composed of alloys of aluminum, copper, and silicon, and contain about 10 wt % of silicon.

Since this silicon is not a metal material, it reduces thermal conductivity.

In the case of aluminum 1050, aluminum sheet (plate) produced by an actual rolling process has a thermal conductivity of 237 W/mk, while the aluminum die-casting materials have a thermal conductivity of only 96 to 100 W/mk.

As a technology related to resolving these problems, “Heat sink structure and manufacturing method thereof” (Korean Patent Publication No. 10-2024-0016878, Patent Literature 1) discloses a case in which a heat sink body part and a heat dissipation fin part are joined by laser welding, so that the heat sink body part can be made of a single cast aluminum part with high thermal conductivity.

In the above-mentioned Patent Literature 1, the heat dissipation fins can be made very thin by welding them to the heat sink body, thereby ensuring sufficient heat dissipation surface area and improving heat dissipation efficiency.

In the meantime, the key in heat dissipation technology is to minimize the air cap between the heat source and the heat sink. However, as mentioned above, in a case of the conventional die-casting heat sink, there is also a problem in that the heat dissipation effect is reduced because the air cap could not be minimized due to the die-casting molding being performed to maximize the heat dissipation effect by maximizing the air contact area and the heat sink manufacturer and the lower component manufacturer being different from each other.

Rather, in “Electronic device enclosures and heat sink structure with thermal management features” (Korean Patent Registration No. 10-1472721, Patent Literature 2), an air gap is formed inside the housing surrounding the heat sink structure. The air gap in this patent Literature 2 provides a uniform heat transfer effect, but as anyone skilled in the art would know, in order to increase the heat dissipation effect, the air gap must be minimized, and this is even more necessary for heat dissipation components with a multilayer structure.

FIG. 1 illustrates a structure of layers for heat dissipation of AP chips in current smartphones. From top to bottom, it takes the layers of vapor chamber, PCM/Gap Pad, shielding sheet, paste, shield can, and AP chip, and the shielding sheet takes the structure of ceramic heat dissipation coating, plating fabric, and conductive adhesive. However, since there are too many layers, the occurrence of air caps increases, making effective heat dissipation difficult, and causing many problems due to heat generation issues.

Here, an opening is formed in the shield can, so that the heat generated from the chip is transferred to the thermal conductive sheet through the opening.

Of course, there are also examples of placing a thermally conductive sheet in this opening, but since an air gap is generated on the adhesive surface of this thermally conductive sheet, it is insufficient to solve the problem of heat generation.

Meanwhile, an emissivity refers to the efficiency of surface energy emission of an object when radiating heat, and thermal radiation (emission) is electromagnetic radiation, including both visible light and invisible infrared rays, and is a numerical value of the heat energy absorbed or emitted by the surface of water.

In general, the higher the emissivity value, the more heat energy is emitted to the outside.

The emissivity value of the pure aluminum plate is measured as 0.513 W/mk as shown in FIG. 2, and when the same material is subjected to a heat dissipative coating, the emissivity is measured as 0.901 W/mk as shown in FIG. 3. Therefore, it can be seen that the emissivity is improved after the heat-dissipative coating, releasing more heat energy than before the coating, thereby significantly improving the heat dissipation effect.

Generally, the heat dissipation effect is improved by 10 to 15 degrees based on 100 degrees Celsius, compared to a pure aluminum material before coating.

Since the pure aluminum plates release only about 50% of the heat and retain it as internal heat, the heat dissipation effect of the chip is low. However, after heat dissipation coating, since about 90% of the heat is released and about 10% is retained as internal heat, when heat dissipation coating is applied to the surface of the aluminum heat sink, the heat dissipation effect can be improved.

However, when applying the existing heat-dissipating coating to the aluminum die-casting materials, it is necessary to apply heat-dissipating paint after chromating for durability in order to prevent corrosion and strengthen adhesion as a pretreatment.

In this case, the cost of painting is high, so the heat dissipation coating is usually not applied to the die-cast material.

In the end, since the performance of the chip continues to improve through upgrades, the heat generated by the chip increases, so that the size of the heat sink has no choice but to increase in order to solve this problem.

In addition, as an example of why the heat sink is made of aluminum die-casting material, when multiple heat sources with different heights are placed at the bottom of the heat sink, multiple protrusions with different heights are usually placed at the bottom to release the heat from the heat sources. At this time, the die-casting material is also used to form these multiple protrusions.

However, as mentioned above, the die-casting material has limitations, which causes the problem of reduced heat dissipation performance.

### PATENT LITERATURE

Patent Literature 1: Korean Patent Publication No. 10-2024-0016878 (Feb. 6, 2024)
Patent Literature 2: Korean Patent Registration No. 10-1472721 (Dec. 8, 2014)

### SUMMARY OF THE PRESENT INVENTION

A high-heat-dissipation hybrid-composite heat sink of the present invention aims to solve the problems arising in the prior art described above and is to provide an ultra-compact and ultra-light heat dissipation structure that improves heat dissipation performance and has light weight and small volume by solving problems of a die casting material in the prior art which has heat dissipation performance degraded due to inclusion of a foreign substance and has large volume and heavy weight.

More specifically, unlike die casting which is a metal casting process of forcing molten metal to be injected into a mold under high pressure, the present invention is to provide a heat sink having high heat dissipation performance for the same weight and volume, the heat sink being made of a plate, an extruded material, a vapor chamber, a heat pipe, or the like which has a maximized content of metal with a high thermal conductivity to minimize weight and volume compared to the die casting material and minimizing the number of layers by performing surface-to-surface bonding to an attachment under the heat sink such as interfacial bonding while air gaps are minimized compared to the prior art.

In addition, the heat dissipation performance is to be prevented from being degraded even while the weight and the volume can be reduced by using a pure plate-shaped metal material, instead of the die casting material, as a heat sink material, and performing direct surface-to-surface interfacial bonding such as a welding method on protrusions at a bottom as described above.

Further, although there may be a need for space for a mounting tolerance between the heat sink and the attachment, heat dissipation effects are to be prevented from being degraded while conditions for lightweight and compact design is satisfied by positioning TIM in this space.

According to an aspect of the present invention to achieve the object described above, there is provided a high-heat-dissipation hybrid-composite heat sink including: a heat sink that is made of any one of materials such as aluminum, copper, magnesium, stainless steel, gold, silver, titanium, iron, nickel brass, carbon fiber, and clad metal and is formed in any one form of a plate, an extruded material, a vapor chamber, or a heat pipe; and an attachment that is positioned under the heat sink and is either bonded to the heat sink without an air gap or press-formed integrally with the heat sink.

In the above configuration, the attachment is surface-bonded to the heat sink without an air gap by any one method of arc stud welding, ultrasonic welding, spark plasma sintering welding, laser welding, brazing, soldering, or insulation bonding.

In the above configuration, the attachment is any one of a heat spreader or a shield can.

In the above configuration, on the heat sink, a heat dissipation coating layer is formed by roll coating.

In the above configuration, the heat sink is pressed to have a wall surface formed at an outer peripheral edge and has undersurface protrusions on an undersurface, the protrusions being bonded by any one method of arc stud welding, ultrasonic welding, spark plasma sintering welding, laser welding, brazing, soldering, or insulation bonding.

In the above configuration, in a case where the attachment is the shield can, the shield has an airtight structure with a closed upper surface, and under the shield can, a TIM and an AP chip are sequentially arranged.

In the above configuration, between the heat sink and the attachment, a TIM for mounting tolerance is positioned.

In the above configuration, on the heat sink, a heat dissipation fin is mounted through welding.

### BRIEF DESCRIPTION OF THE DRAWINGS

The above and other objects, features and advantages of the present invention will be more apparent from the following detailed description taken in conjunction with the accompanying drawings, in which:

FIG. 1 is a drawing showing a layer structure for the heat dissipation of an AP chip a smartphone;

FIG. 2 is a test report showing an emissivity of an aluminum plate;

FIG. 3 is a test report showing an emissivity after heat dissipation coating treatment on an aluminum plate;

FIG. 4 is a drawing showing a general heat dissipation structure of a chip including a heat spreader;

FIG. 5 is a drawing showing a layer structure for the heat dissipation of an AP chip in a typical smartphone;

FIGS. 6A to 6J are drawings showing an embodiment of the present invention;

FIG. 7 is a drawing showing a comparison of the interface structure of a conventional heat dissipation method and a heat dissipation method of the present invention;

FIG. 8 is a photograph showing a specimen for a heat dissipation test in the present invention;

FIG. 9 is a photograph showing equipment settings and experimental results for the heat dissipation test of a die-casting material;

FIG. 10 and FIG. 11 are photographs showing equipment settings and experimental results for the heat dissipation test of a heat dissipation coated aluminum plate;

FIG. 12 is a photograph showing a protrusion on the bottom of a heat sink of a general die casting material;

FIGS. 13A to 13D are drawings showing an example of the arc stud welding for forming a protrusion corresponding to the protrusion of FIG. 12; and

FIG. 14 is a process diagram showing an example of a process for manufacturing a heat sink of the present invention.

### REFERENCE SIGNS LIST

1: heat sink
2: TIM
3: heat spreader
4: Si die
5: AP chip
6: paste
7: shield can
8: shielding sheet
9: PCM
10: chip die
11: heat dissipation coating layer
12: chip

### DETAILED DESCRIPTION OF THE PREFERRED EMBODIMENT

Hereinafter, a high-heat-dissipation hybrid-composite heat sink of the present invention will be described in detail with reference to the accompanying drawings.

The ultra-compact high-heat-dissipation hybrid-composite heat sink of the present invention includes a heat sink and an attachment under the heat sink.

The heat sink that is a configurational element of the present invention is made of any one of materials such as aluminum, copper, magnesium, stainless steel, gold, silver, titanium, iron, nickel brass, carbon fiber, and clad metal and is formed in any one form of a plate, an extruded material, a vapor chamber, or a heat pipe.

As described above, in the case of an aluminum die casting material, the thermal conductivity is decreased similarly to that of silicon for formability. Hence, in the present invention, a material that has a foreign substance for die casting added is not used.

When aluminum is described as an example, comparison of the advantages and disadvantages between an aluminum plate and an aluminum die casting material is as illustrated in Table 1 below.

TABLE 1

| Item | Plate | Die casting |
|---|---|---|
| Material price | Middle price | Low price |
| Weldability | Very good | Non-weldable |
| Thermoelectric | 237 Watts | 96-100 Watts |
| conductivity | | |
| Shape processing | Partially restricted | Very good |
| Heat dissipation | Good | Bad |
| performance | | |
| Coatability | Good | Fair |

A major disadvantage of the die casting material is critical in that about 10 wt % of a silicon (Si) component is contained and prevents welding.

Consequently, it is practically impossible to produce an integral structure of a heat spreader and the heat sink, and thus it is basically impossible to improve thermal conduction through welding.

Consequently, it is practically impossible for an aluminum die casting material to reduce the weight and the volume of the heat sinks, while an aluminum plate can overcome limitations of shape processing through welding, thereby improving heat dissipation performance while weight, volume, and costs are reduced, and thus the aluminum plate enables simultaneous innovative improvements to be achieved in various aspects.

In this case, a heat dissipation fin can be formed on the heat sink by welding.

An attachment that is a configurational element of the present invention is positioned under the heat sink and is either surface-bonded to the heat sink without an air gap or press-formed integrally with the heat sink.

The attachment can be configured of a heat spreader (3), a shield can (7), or the like.

The heat spreader (3) is an advanced component of a cylindrical heat pipe used for heat transfer, has a flat shape, and is mainly used in a small space where a heat pipe cannot be installed or in a thin electronic device such as a laptop, a smartphone, or a smart pad.

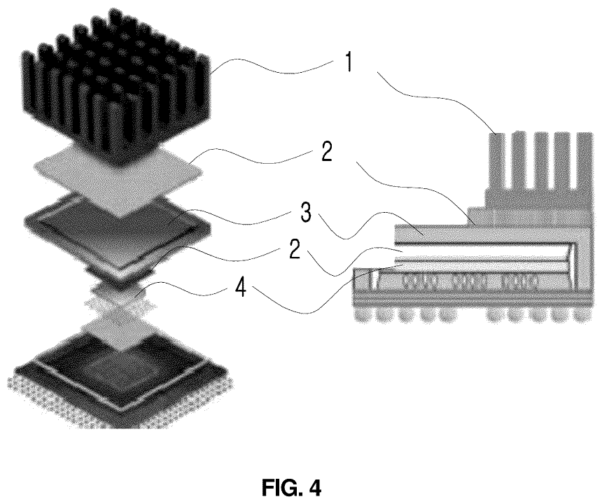

As depicted in FIG. 4, the heat spreader (3) is usually installed on a TIM (2) seated on a Si die (4) on a CPU chip, and a TIM (2) and a heat sink (1) are generally disposed thereon.

Here, the heat sink (1) and heat spreader (3) are usually manufactured separately due to a reason of different manufacturers in the manufacturing processes, and bonding using an adhesive is usually performed with the TIM (2) interposed therebetween.

However, this bonding method inevitably leads to formation of multiple air gaps and results in a decrease in heat dissipation effectiveness.

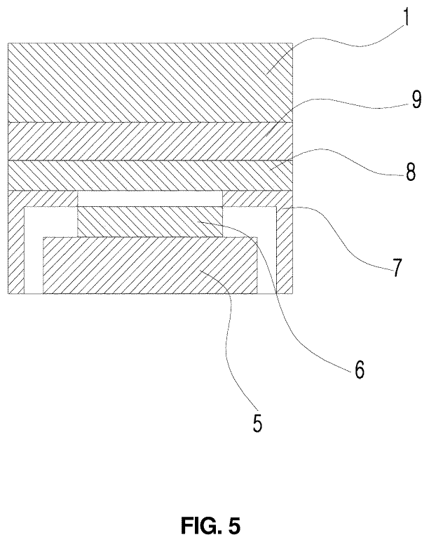

In addition, as depicted in FIG. 5, a layer structure for the heat dissipation of an AP chip of a smartphone is a structure in which the shield can (7) having an open center is positioned above the AP chip (5) in a state where a paste (6) or a TIM is formed, and a shielding sheet (8), a PCM (9), or a gap pad is positioned above the shield can (7), and a heat sink (1) or a vapor chamber is positioned thereon.

Here, the heat sink (1) and the shield can (7) are indirectly connected through the shielding sheet (8) or the PCM (9), and thus a problem arises in that heat dissipation is not effectively performed due to too many layers which lead to an increase in the number of air gaps.

This problem has recently become a topic of discussion as a heating issue of cellular phones manufactured by a company ‘S’.

As described above, an example of a method of performing integral surface-to-surface bonding of the heat sink to the attachment configured of the heat spreader (3), the shield can (7), or the like is any one method of arc stud welding, ultrasonic welding, spark plasma sintering welding, laser welding, brazing, soldering, or insulation bonding.

Insulation bonding refers to using single insulating material such as ALN, BN, SIC, MGO, or alumina or using a combination thereof, during bonding of copper foil and an aluminum sheet used when a metal PCB is manufactured. The insulation bonding can be mostly used at 1 to 10 Watts and enables two effects of facilitating mass bonding and improving vertical thermal conductivity to be simultaneously realized.

The aforementioned bonding methods are methods for enabling surface-to-surface bonding by minimizing air gaps. The arc stud welding is a welding method using basic principles of arc welding and resistance welding and is referred to as STUD, STUD Bolt, STUD Anchor, STUD PIN, or the like.

More specifically, the arc stud welding is generally referred to as stud welding that is a type of melt bonding for joining to a workpiece (base material), an innovative welding method of instantaneously depositing on two surfaces that are to be attached to each other, which is a technical method of bonding members in a certain form in a very economical time and cost and enabling a spatial advantage and mass welding to be achieved.

In addition, corrosion does not occur when a member having a diameter of 3 mm to 10 mm is welded while pressure is applied and joining is performed within a short time (0.1 sec. to 1.0 sec.) in a state in which the base material and the member are sufficiently heated by the electric arc and are melted.

Here, the arc stud welding can be performed on a member having a width of 40 mm depending on the arc capacity. In a case where the width is larger than 40 mm, the arc stud welding can be performed by executing a press process when a corner R value is increased. Depending on a shape, it is possible to use an insulator that is used for bonding copper foil of a metal PCB and an aluminum sheet.

The ultrasonic welding is a method of performing conversion to ultrasonic vibrational energy, transmitting the energy to a bonding target material, and bonding the material by pressure and heat generated due to friction. The ultrasonic welding is advantageous in that lower pressure is applied compared to cold pressure welding such that deformation is small, welding is performed in the same state as rolled, and dissimilar metal welding can be performed.

Moreover, very thin plates, that is, films, can also be easily welded; however, the welding strength varies significantly depending on thicknesses of the plates, and the thicker the plates, the lower the welding strength.

A welding device includes an ultrasonic generator, a vibrator, a vibration transmission mechanism, and a pressure welding tip. Bonding conditions vary depending on a type of bonding material and a thickness of a plate, but external deformation of a bonding portion is small, and it is easy for mass production.

This bonding method forms a surface-to-surface interfacial bonding surface, thus enabling no external damage and no deformation to occur and heat loss to be minimized.

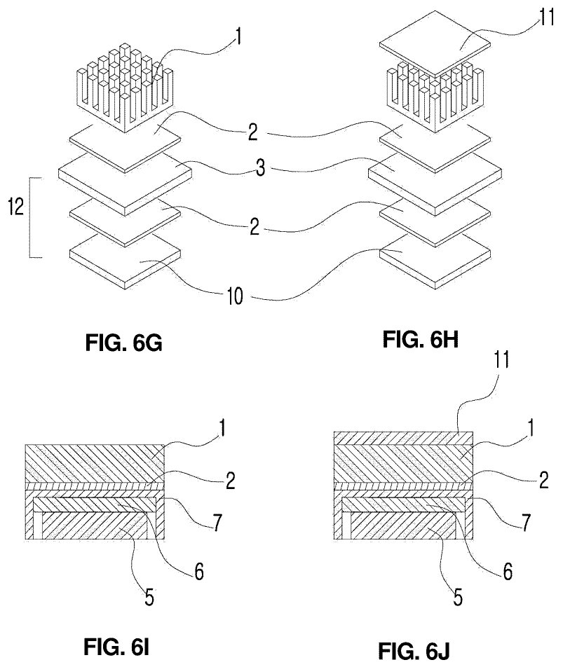

FIG. 7 specifically depicts a difference between the existing structure and a structure according to the present invention. In the prior art, an air gap that is not actually visible is formed in an interface between a heat spreader and a heat sink, and a phenomenon occurs in which this part blocks heat, increases thermal resistance, and hinders heat dissipation. Hence, to reduce this phenomenon, a gel or a phase change material (PCM) sheet is used, but these products are also significantly less effective in reducing the interface. However, it can be found that the structure of the present invention on the right side completely eliminates the air gap to reduce an insulation effect and enables smooth heat dissipation to be performed.

In the above configuration, a heat dissipation coating layer can be formed on the heat sink by roll coating.

The heat dissipation coating layer receives heat from the heat sink and dissipates and radiates the heat to the outside and can be made of various known heat dissipation coating materials.

Examples thereof include carbon nanotubes (CNT), nano ceramic, graphene, graphite, urethane, epoxy, silicone, acryl, PVDF, Teflon, and the like.

In this case, roll coating is suitable instead of spray coating, and can reduce consumption of a heat dissipation coating material to cut down manufacturing costs.

In a case where the heat dissipation coating layer is formed on the heat sink, the emissivity increases based on a pure aluminum plate as described in background art, and thereby the heat dissipation effect increases.

Furthermore, in a case where the heat dissipation coating layer is applied to an upper side of a heat sink, such as the aluminum plate sheet described above, it is possible to reduce the weight and the volume by about ⅔ compared to a case of using only the die casting heat sink material, and thus not only the heat dissipation effect but also the lightweight and compact design can be achieved.

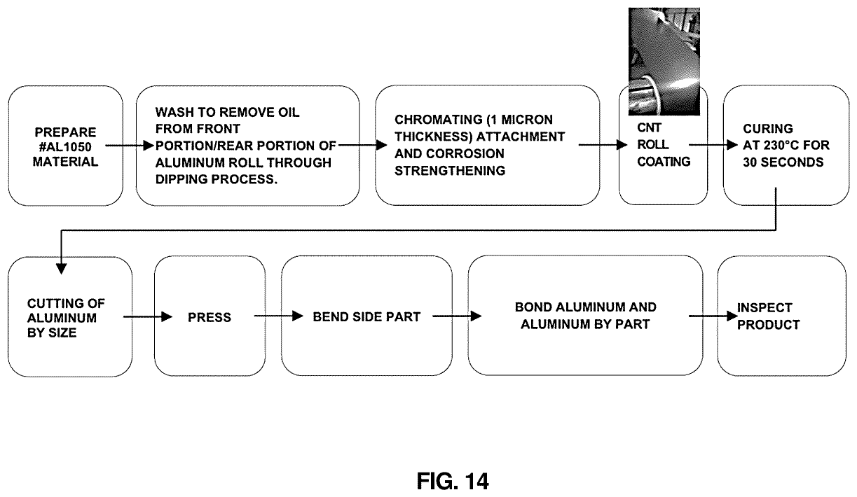

FIG. 14 depicts an example of a process of manufacturing the heat sink of the present invention in which the heat dissipation coating layer is formed.

In the drawing, it can be found that, after an aluminum plate is prepared and a front surface portion and a rear surface portion thereof is cleaned through a dipping process, the plate is coated with chromate for corrosion prevention, is coated with a CNT heat dissipation coating material by a roll coating method, cured, cut to match a product shape, and press-formed, a side is bent if necessary, the protrusion is formed for each portion in a case where undersurface protrusions need to be provided, and then the attachment is bonded to the plate to manufacture a product.

### <Experimental Example 1> Heat Dissipation Test

A heat dissipation test was conducted.

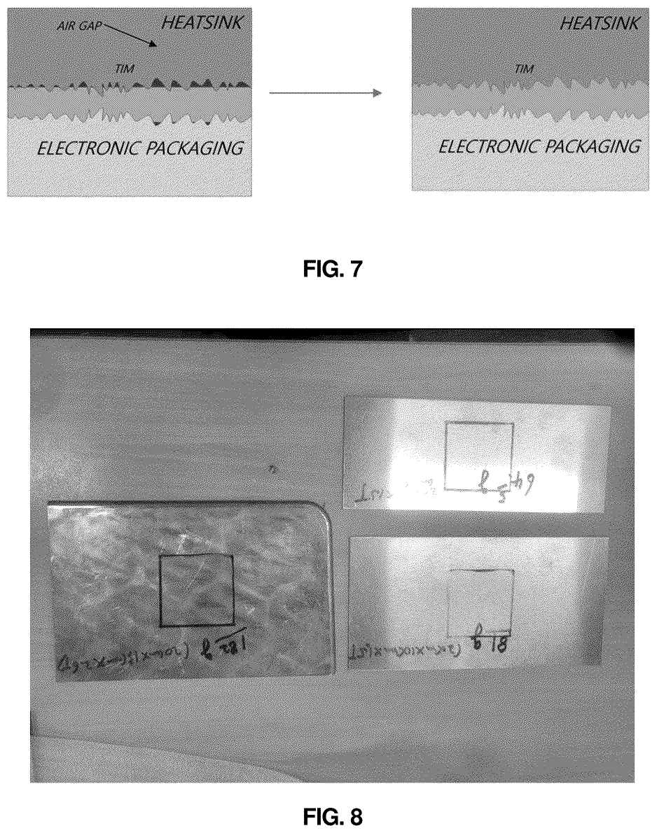

First, an aluminum die casting material having a size of 20 cm×13 cm×2.6 T and weight of 182 g, a CNT coated aluminum #1050 plate having a size of 20 cm×10 cm×1.5 T and weight of 81 g, and a CNT coated aluminum #1050 plate having a size of 20 cm×8 cm×1.5 T and weight of 64.5 g are prepared (see FIG. 8).

Additionally, after a power supply, a temperature recorder, and a copper block equipped with an internal heater are prepared, heating is performed with input power of 30 Watts for one hour, and then temperatures at an initial state and after heating for one hour were measured.

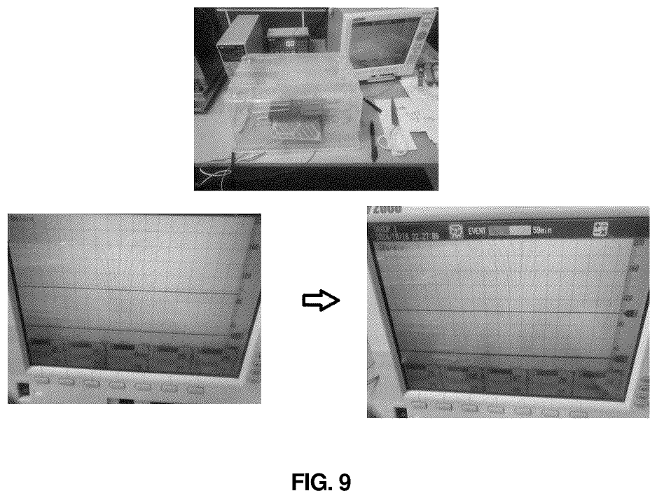

Heat source temperatures and indoor temperatures per unit time of the die casting material are listed in Table 2 below and FIG. 9.

TABLE 2

| | Heat source | Indoor |
|---|---|---|
| Test time | temperature (° C.) | temperature (° C.) |
| 0 min | 26.3 | 25.9 |
| 20 min | 81.7 | 26.0 |
| 30 min | 91.1 | 26.1 |
| 40 min | 96.3 | 26.1 |
| 50 min | 99.2 | 26.0 |
| 60 min | 100.8 | 26.1 |

On a monitor screen in FIG. 9, number 2 indicates the heat source temperature, number 4 indicates the indoor temperature, and the test times of 0 min. and 60 min. are illustrated in FIG. 9.

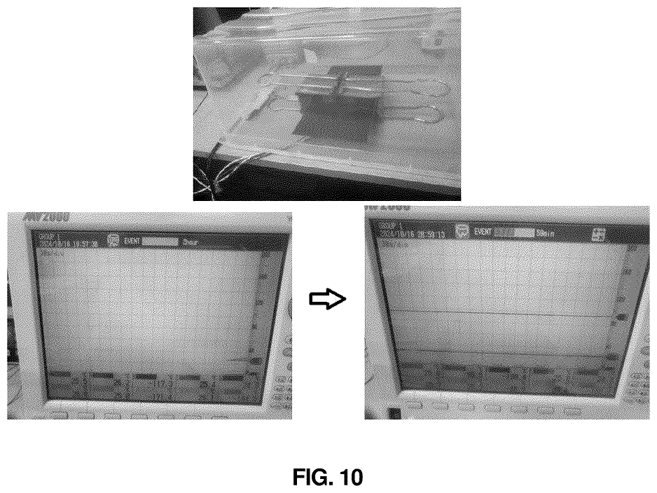

The heat source temperatures and the indoor temperatures per unit time of the CNT coated aluminum #1050 plate having the size of 20 cm×10 cm×1.5 T and the weight of 81 g are illustrated in Table 3 below and FIG. 10.

TABLE 3

| | Heat source | Indoor |
|---|---|---|
| Test time | temperature (° C.) | temperature (° C.) |
| 0 min | 26.2 | 25.4 |
| 20 min | 83.3 | 25.6 |
| 30 min | 89.9 | 25.8 |
| 40 min | 93.0 | 25.8 |
| 50 min | 94.6 | 25.9 |
| 60 min | 95.5 | 25.9 |

On a monitor screen in FIG. 10, number 2 indicates the heat source temperature, number 4 indicates the indoor temperature, and the test times of 0 min. and 60 min. are illustrated in FIG. 10.

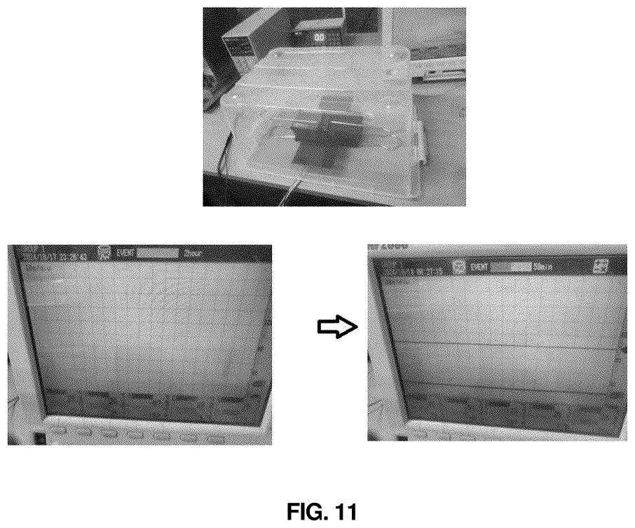

The heat source temperatures and the indoor temperatures per unit time of the CNT coated aluminum #1050 plate having the size of 20 cm×8 cm×1.5 T and the weight of 64.5 g are illustrated in Table 4 below and FIG. 11.

TABLE 4

| | Heat source | Indoor |
|---|---|---|
| Test time | temperature (° C.) | temperature (° C.) |
| 0 min | 26.2 | 26.0 |
| 20 min | 88.1 | 26.2 |
| 30 min | 95.5 | 26.2 |
| 40 min | 99.1 | 26.2 |
| 50 min | 100.8 | 26.2 |
| 60 min | 101.7 | 26.2 |

The results of the experiment are summarized and listed in Table 5.

TABLE 5

| | Item | | | | | |
|---|---|---|---|---|---|---|
| | Diecasting | | CNT coating | | CNT coating | |
| | (20 cm × 13 | | (20 cm × 10 | | (20 cm × 8 | |
| | cm × 2.6 T) | | cm × 1.5 T) | | cm × 1.5 T) | |
| Weight | 182 | g | 81 | g | 64.5 | g |
| Volume | 0.026 cm × 20 | | 0.015 cm × 20 | | 0.015 cm × 20 | |
| | cm × 13 cm = | | cm × 10 cm = | | cm × 8 cm = | |
| | 6.76 cm³ | | 3 cm³ | | 2.4 cm³ | |
| Test Voltage | 30 | watts | 30 | watts | 30 | watts |
| Heat dissipation | 1 | hour | 1 | hour | 1 | hour |
| test time | | | | | | |
| Temperature | 100.8 | (° C.) | 95.5 | (° C.) | 101.7 | (° C.) |

Assuming that similar temperature results are obtained after one hour as a result of the experiment, the aluminum die casting material weighs 182 g while the CNT coated aluminum plates weigh 81 g and 64.5 g. Hence, it can be found that the weight required for a similar heat dissipation effect is much lighter.

Similarly, in the case of the volume, it can be found that the aluminum die casting material has a volume of 6.76 cm3 while the CNT coated aluminum plates have smaller volumes of 3 cm3 and 2.4 cm3.

That is, weight reduction of 63%, volume reduction of 65%, cost reduction of 30% can be achieved, and the heat dissipation performance can be improved by 50% or higher.

In the above-described configuration, it is preferable that an undersurface protrusion be formed on an undersurface of the heat sink to overcome a step of the attachment.

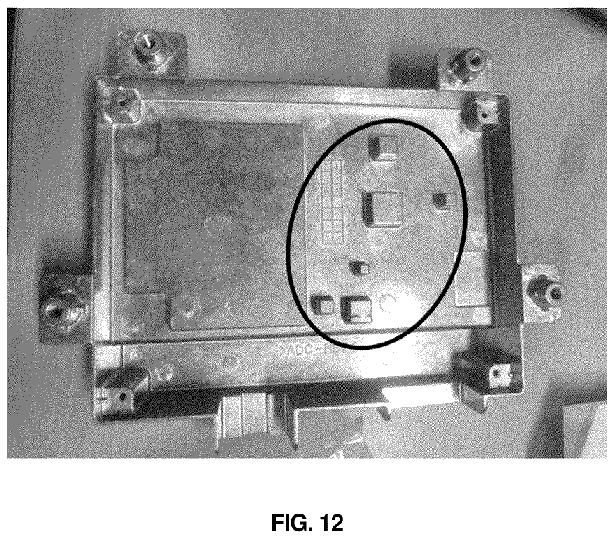

FIG. 12 illustrates a heat sink made of a general die casting material, with protrusions having different protrusion lengths which are formed to be in contact with chips having various heights.

This means that multiple resistors and chips are arranged under the heatsink and are formed with different heights to be in contact with the heat sink in a case where the resistors and the chips have different heights, respectively.

The protrusions can also be required by the present invention, and the heat sink made of a plate can be formed by press-forming the plate into a required shape.

Incidentally, in a case where multiple heat sources having different heights are arranged below the heat sink in general, multiple protrusions having different heights are formed to be in contact with these heat sources.

Incidentally, as described above, in a case where a heat sink is manufactured using a method of press-forming, there are difficulties in forming these protrusions having different heights.

In order to solve the difficulties, the undersurface protrusions formed on the undersurface of the heat sink can be formed by a method such as arc stud welding or ultrasonic welding, similar to the bonding of the heat sink and the attachment.

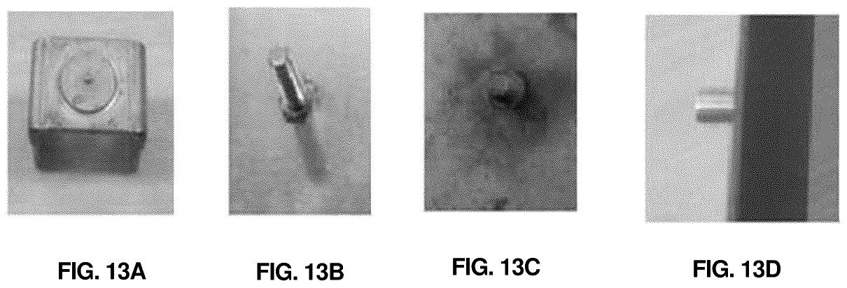

FIGS. 13A to 13D depict an example of the arc stud welding for this purpose.

First, in FIGS. 13B, 13C, and 13D, protrusions can be formed at low costs by bonding aluminum to aluminum or aluminum to copper through stud welding and then manufacturing male screws in round or quadrangular shapes depending on heights of PCB board components.

Further, the protrusions of FIG. 13A enable both surfaces to be completely melted and bonded and maximum heat dissipation effects to be maintained, and in the case of FIG. 13D, melting and bonding can be completely achieved without any damage to a coated surface.

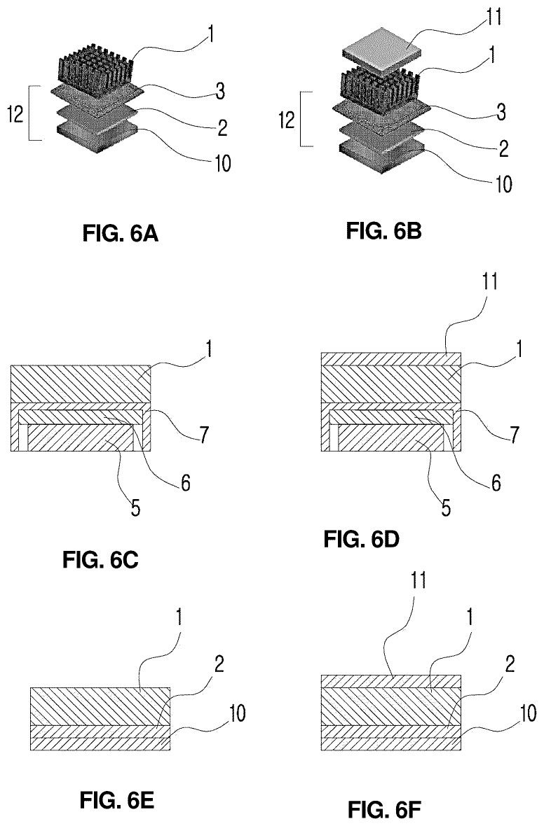

A specific example of the present invention configured as described above is depicted in FIGS. 6A to 6F.

In FIG. 6A, a structure is illustrated in which the heat sink (1), the heat spreader (3), the TIM (2), and a chip die (10) are continuously layered. Here, the heat spreader (3), the TIM (2), and the die (10) constitutes a chip (12).

Here, the chip (12) includes an AP, a CPU, a GPU, an APU, an NPU, a TPU, an application-specific integrated circuit (ASIC), or the like.

As described above, the heat sink (1) is made of any one of materials such as aluminum, copper, magnesium, stainless steel, gold, silver, titanium, iron, nickel brass, carbon fiber, and clad metal and is formed in any one form of a plate, an extruded material, a vapor chamber, or a heat pipe. The TIM (2) is made up of a PCM sheet, a heat dissipation tape, a heat dissipation gel, a thermal pad, an epoxy adhesive, or the like, based on a raw material such as silicone, carbon fiber, acryl, and urethane, and the die (10) is a silicon (Si) die.

Here, the heat sink (1) and the heat spreader (3) are bonded by surface-to-surface interfacial bonding described above by the above-described bonding method.

The heat spreader (3) is made of clad metal obtained by inducing bonding between the dissimilar metals (such as aluminum and copper) by bonding the two or more metals under high pressure and then expanding and annealing the bonded metals, copper, silver, nickel plated copper, silver coated copper, or the like.

The heat sink (1) may include a simple plate, and heat dissipation fins may be integrally bonded on the heat sink (1).

FIG. 6B has the same configuration as (A) thereof, and the above-described heat dissipation coating layer (11) is formed on the heat sink (1).

In a case where the heat sink (1) is made of a simple plate, the heat dissipation coating layer (11) can be formed by a roll coating method. When it is difficult to perform the roll coating, a spray coating method can be employed when heat dissipation fins are formed.

The heat dissipation coating layer (11) can be made of the above-described carbon nanotubes (CNT), nano ceramic, graphene, graphite, urethane, epoxy, silicone, acryl, PVDF, Teflon, or the like.

FIG. 6C illustrates an example in which the heat sink (1), the shield can (7), the paste (6) or the TIM, and the AP chip (5) are sequentially formed from top to bottom.

Here, instead of the AP chip (5), a CPU chip, an APU chip, an NPU chip, a TPU chip, an ASIC chip, or the like may be applied.

As is well known, the shield can (7) can be made of nickel brass such as C7521, C7541, or C7701, and the heat sink (1) includes a vapor chamber.

Here, the heat sink (1) and the shield can (7) are bonded by surface-to-surface interfacial bonding described above by the above-described bonding method.

FIG. 6D illustrates a configuration similar to that in FIG. 6C, but with the heat dissipation coating layer (11) is coated on the heat sink (1).

FIG. 6E illustrates an example in which the heat sink (1), the TIM (2), and the chip die (10) are continuously formed from top to bottom, and the heat sink (1) and the heat spreader (3) are made of an integral plate processed by a CNC machine. FIG. 6F illustrates an example in which manufacturing is performed in the same way as FIG. 6E, but with a coating process performed on the heat dissipation coating layer (11).

Manufacturing costs of this structure are high, but this structure has the best heat dissipation performance. Hence, when this structure is applied to an AI data center having a problem of high heat, the problem of high heat generated during an GPU operation can be solved.

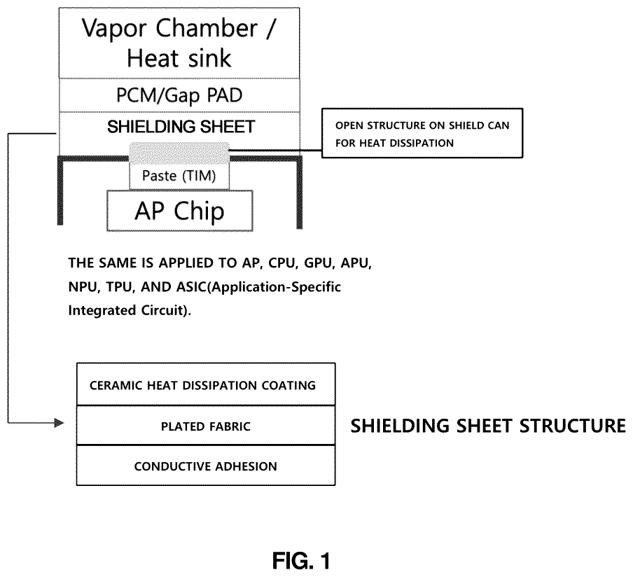

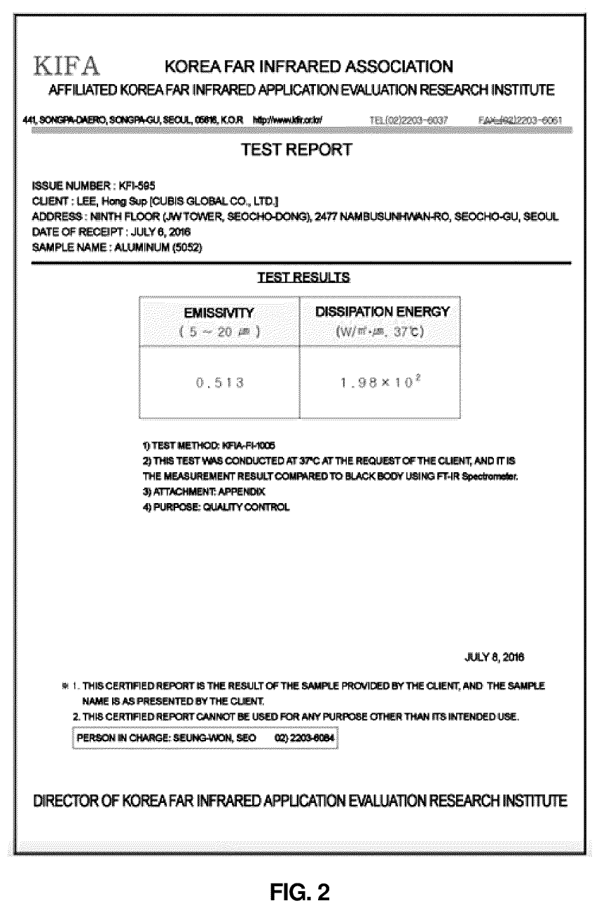

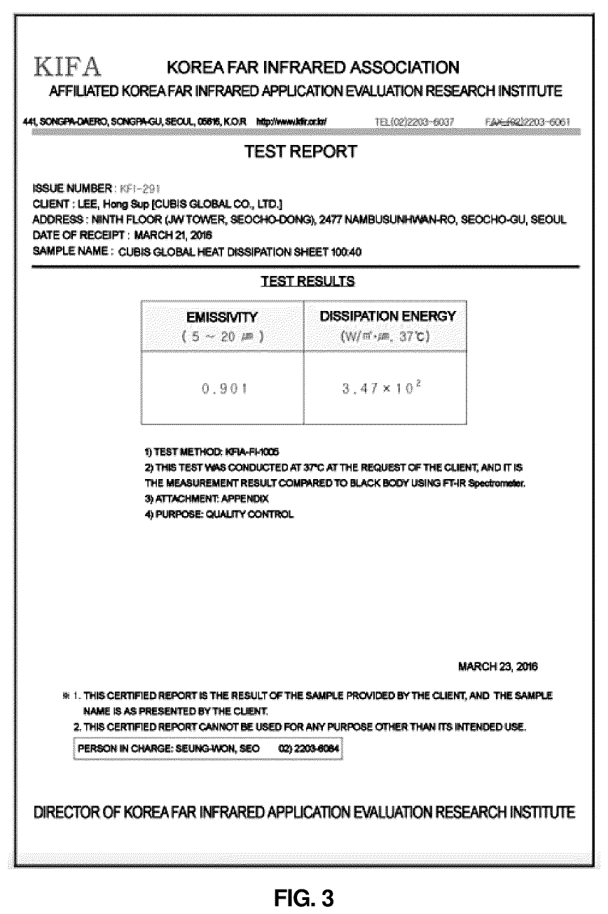

With reference to a structure in FIG. 6C, compared to the structure of the prior art in FIG. 1, a basic four-layer configuration of the heat sink (1), the shield can (7), the paste (6) or the TIM, and the AP chip (5) is illustrated, and even a structure of (D) in which the heat dissipation coating is performed has only five layers. Hence, it can be found that the number of layers is significantly reduced compared to the structure of the prior art in FIG. 1.

Consequently, the air gap is still further reduced, and thus good heat dissipation performance is achieved.

Additionally, the structure of the prior art in FIG. 1 uses fiber fabric, so even if fiber fabric is plated, the vertical thermal conductivity is 2 W/mk or lower, and thus it is basically impossible to transfer much heat from the AP chip to the vapor chamber. In contrast, in the example, the fiber fabric is excluded by performing bonding of the vapor chamber and the shield can, and materials having high vertical thermal conductivity are used in a structure in which pure metals are in continuous contact with each other through interfacial adhesion of the shield can made of nickel brass (61.67 wt % of copper, 0.5 wt % of manganese, 16.5 to 19.5 wt % of nickel, and zinc as balance) and the metal vapor chamber. Hence, the heat dissipation effect is improved by at least 8 to 10° C. compared to the structure illustrated in FIG. 1.

Moreover, the heat sink (1) made of a pure material without impurities becomes lighter compared to the heat sinks in the prior art, and the volume of the heat sink (1) can be minimized through the press-forming process.

In providing the heat sink to which the attachment is attached by complete surface-to-surface bonding as described above, the mounting tolerance needs to be provided in an actual current assembly site since components are delivered and assembled individually.

That is, in a case where the heat spreader or the shield can is bonded to the heat sink by a method such as welding, it is difficult to perform assembly depending on site conditions in some cases.

As a measure to cope with these current site conditions, as depicted in FIGS. 6G to 6J, the TIM (2) can be disposed between the heat sink (1) and the heat spreader (3), or between the heat sink (1) and the shield can (7).

In this case, the TIM (2) has preferably a very thin thickness equal to the mounting tolerance, and it is preferable that the TIM (2) be attached as closely as possible to an adjacent configurational element without an air gap.

Alternatively, it may be also possible to allow heat conduction be performed through the part where the mounting tolerance is generated by a method such as welding other than the TIM (2), so that heat transfer can occur as quickly as possible.

Further, in a case where the shield can (7) is applied as the attachment, as in examples FIGS. 6E, 6F, 6I and 6J, it is preferable that this shield can (7) be made of a completely sealed type, unlike the shield can in the prior art which has an opening.

This aims to enable heat transfer to be rapidly performed while minimizing the air gap, thereby being said to be different from the prior art.

The heat sink of the present invention which is configured as described above has greatly improved heat dissipation performance by performing roll coating of an aluminum sheet with heat dissipation coating.

For reference, heat dissipation coating costs can be reduced by 80% compared to the spray coating.

Also, by using an aluminum plate material (thermal conductivity: 237 Watts) instead of the aluminum die casting (thermal conductivity: 96 to 100 Watts) material, a material having approximately 2.4 times better thermal conductivity than that of the die casting material was used to achieve better heat dissipation.

Additionally, a shape inside the heat sink can be implemented almost perfectly like the die casting material by using the interfacial bonding and the press-forming process, and significant reduction in the thermal resistance by eliminating a middle interface enables the heat dissipation performance to be maximized and the lightweight and slim volume design to be realized.

Here, it is found that a key factor of the heat dissipation is a key factor that determines heat dissipation which is minimizing boundaries between layers and eliminating the air gap between the heat source and the heat sink as much as possible, and a perfect heat dissipation effect is realized by using several additional bonding positions to send a temperature of the heat source to the heat sink without any air gap through melted bonding of both surfaces of the heat source and the heat sink or a material therebetween and the heat sink. It is possible to drastically reduce the number of layers and improve the weight, the volume, and the cost-effectiveness for a heat sink in autonomous driving, a metal PCB, an AP chip, a CPU, an LED, an OLED TV, Telecom, an VAG Display card, an AI Server, and a Gaming console, which have been unresolved problems until now.

According to the present invention, the high-heat-dissipation hybrid-composite heat sink is to provide an ultra-compact and ultra-light heat dissipation structure that improves heat dissipation performance and has light weight and small volume by solving problems of a die casting material in the prior art which has heat dissipation performance degraded due to inclusion of a foreign substance and has large volume and heavy weight.

More specifically, unlike die casting which is a metal casting process of forcing molten metal to be injected into a mold under high pressure, the present invention is to provide a heat sink having high heat dissipation performance for the same weight and volume, the heat sink being made of a plate, an extruded material, a vapor chamber, a heat pipe, or the like which has a maximized content of metal with a high thermal conductivity to minimize weight and volume compared to the die casting material and minimizing the number of layers by performing surface-to-surface bonding to an attachment under the heat sink such as interfacial bonding while air gaps are minimized compared to the prior art.

In addition, the heat dissipation performance is to be prevented from being degraded even while the weight and the volume can be reduced by using a pure plate-shaped metal material, instead of the die casting material, as a heat sink material, and performing direct surface-to-surface interfacial bonding such as a welding method on protrusions at a bottom as described above.

Further, although there may be a need for space for a mounting tolerance between the heat sink and the attachment, heat dissipation effects are to be prevented from being degraded while conditions for lightweight and compact design is satisfied by positioning TIM in this space.

It will be apparent to those skilled in the art that various modifications and variations can be made in the present invention without departing from the spirit or scope of the present invention as defined in the appended claims.

This invention can be implemented in many different forms without departing from technical aspects or main features. Therefore, the implementation examples of this invention are nothing more than simple examples in all respects and will not be interpreted restrictively.

What is claimed is:

1. A high-heat-dissipation hybrid-composite heat sink comprising:
a heat sink that is made of any one of materials such as aluminum, copper, magnesium, stainless steel, gold, silver, titanium, iron, nickel brass, carbon fiber, and clad metal and is formed in any one form of a plate, an extruded material, a vapor chamber, or a heat pipe; and
an attachment that is positioned under the heat sink and is either bonded to the heat sink without an air gap or press-formed integrally with the heat sink.

2. The high-heat-dissipation hybrid-composite heat sink according to claim 1,
wherein the attachment is surface-bonded to the heat sink without an air gap by any one method of arc stud welding, ultrasonic welding, spark plasma sintering welding, laser welding, brazing, soldering, or insulation bonding.

3. The high-heat-dissipation hybrid-composite heat sink according to claim 2,
wherein the attachment is any one of a heat spreader or a shield can.

4. The high-heat-dissipation hybrid-composite heat sink according to claim 1,
wherein, on the heat sink, a heat dissipation coating layer is formed by roll coating.

5. The high-heat-dissipation hybrid-composite heat sink according to claim 1,
wherein the heat sink is pressed to have a wall surface formed at an outer peripheral edge and has undersurface protrusions on an undersurface, the protrusions being bonded by any one method of arc stud welding, ultrasonic welding, spark plasma sintering welding, laser welding, brazing, soldering, or insulation bonding.

6. The high-heat-dissipation hybrid-composite heat sink according to claim 3,
wherein, in a case where the attachment is the shield can, the shield has an airtight structure with a closed upper surface, and
under the shield can, a TIM and an AP chip are sequentially arranged.

7. The high-heat-dissipation hybrid-composite heat sink according to claim 1,
wherein, between the heat sink and the attachment, a TIM for mounting tolerance is positioned.

8. The high-heat-dissipation hybrid-composite heat sink according to claim 1,
wherein, on the heat sink, a heat dissipation fin is mounted through welding.
